(19) United States
(12) Patent Application Publication
(10) Pub. No.: US 2011/0221464 A1
(43) Pub. Date: Sep. 15, 2011

(54) CONTACT PROBE AND SOCKET, AND MANUFACTURING METHOD OF TUBE PLUNGER AND CONTACT PROBE

(75) Inventors: Takahiro Nagata, Gunma (JP); Takayoshi Okuno, Gunma (JP); Shin Sakiyama, Tokyo (JP); Masanori Nagashima, Tokyo (JP)

(73) Assignee: ADVANTEST CORPORATION, Tokyo (JP)

(21) Appl. No.: 13/040,291

(22) Filed: Mar. 4, 2011

(30) Foreign Application Priority Data
Mar. 12, 2010 (JP) 2010-055641

(51) Int. Cl. G01R 1/067; B21C 23/24; H01R 43/16

(52) U.S. Cl. 324/755.05; 72/47; 29/874

(57) ABSTRACT

A contact probe has a tubular plunger which is not made by press working and rounding so that quality control of gold plating or the like is not necessary or not difficult. The tubular plunger is made of a metal tube with a tip that has a reduced outside diameter and notches spaced from the tip. The tip is bent inside the tube and an outer surface of the metal tube, from a bent part to a bottom side, with a small diameter defining a convex part having a larger diameter. The small diameter part of the metal tube is cut off at the end of the small diameter.

### BACKGROUND OF THE INVENTION

1. Field of the Invention

The present invention relates to a contact probe and a socket, and manufacturing method of a tube plunger and the contact probe, which are utilized for measuring a device to be measured such as a semiconductor integrated circuit etc.

2. Description of the Related Art

In case of measuring a device to be measured such as semiconductor integrated circuit etc., contact probes are generally used for electrically connecting between the device to be measured and a test board of a measuring instrument side.

(Related Art 1)

FIG. 13 is an outline cross-sectional view of a structure example of a conventional contact probe. The contact probe 800 shown in FIG. 13 has two plungers 809, 810 and a coil spring 803 which is inserted inwardly between plungers 809, 810. One of the plungers, that is plunger 809, is used for contact with a solder ball 805 of a test object 804 (DUT). The other of the plungers, that is plunger 810, is used for contact with a contact pad 806 of a test board 807 (DUT board). The plungers 809, 810 have a hole to form a bag-like hollow structure respectively, and a tip side inner surface of the each plunger is a bottom of the hole. Both ends of a coil spring 803 touch the tip side inner surfaces of the plungers 809, 810 respectively to prevent the coil spring 803 from dropping out. And the coil spring 803 energizes plungers 809, 810 in a direction to apart from each other. Therefore, it causes plungers 809, 810 to provide contact force on the solder ball 805 of the test object 804 and the contact pad 806 of the test board 807 respectively. Typically, a plurality of contact probes 800 are supported by housing 8.

FIGS. 14A to 14F are explanatory views, which show a conventional manufacturing process of the plunger that is the bag-like hollow structure used for the conventional contact probe as shown in FIG. 13. As shown in FIG. 14A, a metal rod 820 is held by a chuck 850 of a machine tool such as a lathe etc. As shown in FIG. 14B, a tip of the metal rod 820 is made to be a shape suitable for contact with the test object by cutting work. In an outside diameter working afterwards, diameter of the tip side of the metal rod 820 is reduced by shaving (cutting) as shown in FIG. 14C and a convex part 823 for preventing drop out is formed. As shown in FIG. 14D, the tip side of the metal rod 820 is held by another chuck 860 and the metal rod 820 is cut off at a predetermined position. A hole working is prosecuted to an end side plane (cutting plane) of the metal rod 820 by a drill (not shown) as shown in FIG. 14E, and gold (Au) plating is done finally.

(Related Art 2)

FIG. 15 is an outline cross-sectional view of another structure example of a conventional contact probe. The contact probe 900 shown in FIG. 15 has two plungers 811, 812 which open at a tip end and are incurvated different from the bag-like hollow structure shown in FIG. 13. The plunger as mentioned is obtained as follows: At first a mother metal plate 920 is made with punching of a press working as shown in FIG. 16A. The punched mother metal plate 920 is made round by a round bending working so that a shape of the plunger shown in FIG. 16B is formed. Finally, gold (Au) plating is prosecuted on it.

Related arts of the invention are as follows:

Japanese Patent Application Laid-Open No. 2005-9925

Japanese Patent Application Laid-Open No. 2008-39496

In case of the related art 1 shown in FIG. 13, there is a problem that gold plating of the metal of the bag-like hollow structure is necessary as mentioned above in the manufacturing process of the bag-like hollow plunger which is used for the contact probe in the related art 1, so that quality control of the gold plating is difficult inside of the bag hole of the bag-like hollow structure. It is also necessary to make the hole by drill working etc. as shown in FIG. 14E, thus the manufacturing process is complicated.

In case of the related art 2 shown in FIG. 15, there is a problem that a special metal mold is necessary for the press working of the plunger used for the contact probe in the related art 2, so that total cost of manufacturing is increased. The plunger is unsuitable for a minute diameter contact probe to correspond to the test object with terminal arrays of narrow pitch because working accuracy is not good and making the plunger to a minute diameter is also difficult in the manufacturing process of the plunger. Further, it can not avoid that a slit in a longitudinal direction on a side surface of the plunger is caused by the round bending working as shown in FIG. 16B. The slit causes negative affect of sliding motion of the plunger and degrade electrical characteristics of the contact probe.

### SUMMARY OF THE INVENTION

The present invention has been made in view of the foregoing circumstances and problems, and a first object thereof is to provide a contact probe having a tube plunger which does not depend on the press working and the rounding process as mentioned in the related art 2 and to provide a socket including the contact probes, and manufacturing method of the tube plunger and the contact probe.

The second object of the invention is to provide a contact probe having a tube plunger which differs from the bag-like hollow plunger as mentioned in the related art 1 so that hole drilling is not necessary and quality control of plating is not necessary or not difficult when a layer of precious metal or a layer of alloy of which principal ingredient is precious metal should be plated on inner surface of the plunger, and to provide a socket including the contact probes, and manufacturing method of the tube plunger and the contact probe.

First embodiment of the present invention relates a contact probe for electrical interconnection. The contact probe includes: at least one tube plunger which includes none of slits; and a coil spring which is retained by the tube plunger, of which end touches to the tube plunger, so that the coil spring energizes the plunger in a direction to apart from each other.

In the contact probe according to the first embodiment, a part of the coil spring may be inside of the tube plunger. A tip part of the tube plunger is a connection part and is bent inside to be a stopper for retaining the coil spring.

In the contact probe according to the first embodiment, a part of the coil spring may be inside of the tube plunger. A tip part of the tube plunger is a connection part, and a side part of the tube plunger bent inside to be a stopper for retaining the coil spring.

In the contact probe according to the first embodiment, a part of the coil spring may be inside of the tube plunger. A tip part of the tube plunger is a connection part, and the coil spring is retained by a stopper member penetrating through the tube plunger in a diameter direction.

In the contact probe according to the first embodiment, a part of the coil spring may be outside of the tube plunger. A tip part of the tube plunger is a connection part, and a stopper part of outside of the tube plunger retaining the coil spring.

In the contact probe according to the first embodiment, at least a part including a tip of coil spring may be a tightly-wound part.

Second embodiment of the present invention relates a contact probe for electrical interconnection. The contact probe includes: first and second tube plungers which include none of slits; and a coil spring of which one end is retained by a stopper part of the first tube plunger, and of which the other end is retained by a stopper part of the second tube plunger, so that the coil spring energizes the plungers in a direction to apart from each other.

In the contact probe according to the second embodiment, the coil spring may be inside of the first and second tube plunger. Each tip part of the tube plungers is a connection part, each side part of the tube plungers bent inside to be a stopper for retaining the coil spring, and a bottom end side of the second tube plunger is inside of the first tube plunger so as to be slidable each other and not to escape from the first tube plunger.

Third embodiment of the present invention relates a socket. The socket includes an insulation support body, and a plurality of the contact probes according to the first or second embodiment supported by the insulation support body.

Forth embodiment of the present invention relates a manufacturing method of a tube plunger. The embodiment includes: preparing a tubular metal provided with a layer of a precious metal or a precious-metal alloy of which principal ingredient is precious metal, bending inside a side part of the tubular metal.

Fifth embodiment of the present invention relates a manufacturing method of a tube plunger. The embodiment includes: bending inside a side part of the tubular metal, plating at least an inside of the tubular metal with a layer of a precious metal or a precious-metal alloy of which principal ingredient is precious metal after bending.

In the manufacturing method of a tube plunger according to the forth or fifth embodiment, the embodiment may includes further, working of a convex part outside of the tubular metal.

In the manufacturing method of a tube plunger according to the forth or fifth embodiment, the embodiment may includes further, shaving a prescribed length of a tip part of the tubular metal to reduce a diameter thereof before bending, and bending inside a reduced diameter part.

In the manufacturing method of a tube plunger according to the forth or fifth embodiment, the embodiment may includes further, cutting out a plurality of notches from a tip part of the tubular metal, and bending inside the tip part remained.

Sixth embodiment of the present invention relates a manufacturing method of a contact probe. The embodiment includes: preparing a tubular metal provided with a layer of a precious metal or a precious-metal alloy of which principal ingredient is precious metal, bending inside a side part of the tubular metal to form a bending part, inserting one side of a coil spring into inside of the tubular metal of which the bending part is stopper for the coil spring not to escape to the one side.

In the manufacturing method of a contact probe according to the sixth embodiment, the embodiment may includes further, after inserting of the coil spring, forming stopper at bottom side of the tubular metal in comparison with a position of the bending part to prevent the coil spring not to escape to the other side.

In the manufacturing method of a contact probe according to the sixth embodiment, the embodiment may includes further, preparing another tubular metal provided with a layer of a precious metal or a precious-metal alloy of which principal ingredient is precious metal, bending inside a side part of the another tubular metal to form a bending part, assembling both tubular metals and the coil spring, so that bottom side of one of the tubular metal is inside of the other of the tubular metal, the coil spring is inside of the tubular metals and is retained between both bending pats not to escape.

It is to be noted that any arbitrary combination of the above-described structural components as well as the expressions according to the present invention changed among a system and so forth are all effective as and encompassed by the present embodiments.

According to the embodiment, it can be brought to realization to provide a contact probe having a tube plunger which does not depend on the press working and the rounding process as mentioned in the related art 2, to provide a socket including the contact probes, and to provide a manufacturing method of the tube plunger and the contact probe.

According to the embodiment, it can be brought to realization to provide a contact probe having a tube plunger which differs from the bag-like hollow plunger as mentioned in the related art 1 so that hole drilling is not necessary and quality control of plating is not necessary or not difficult when a layer of precious metal or a layer of alloy of which principal ingredient is precious metal should be plated on inner surface of the plunger, to provide a socket including the contact probes, and to provide a manufacturing method of the tube plunger and the contact probe.

### BRIEF DESCRIPTION OF THE DRAWINGS

Embodiments will now be described, by way of example only, with reference to the accompanying drawings which are meant to be exemplary, not limiting, and wherein like elements are numbered alike in several figures, the drawings in which:

FIG. 1A to FIG. 1E are explanatory process flow views of manufacturing method 1 of a tube plunger according to an embodiment of the invention;

FIG. 2A to FIG. 2F are explanatory process flow views of manufacturing method 2 of a tube plunger according to the embodiment of the invention;

FIG. 3A to FIG. 3F are explanatory process flow views of manufacturing method 3 of a tube plunger according to the embodiment of the invention;

FIG. 4A to FIG. 4E are explanatory process flow views of manufacturing method 4 of a tube plunger according to the embodiment of the invention;

FIG. 5 is a cross-sectional view of first structure example of a contact probe according to the embodiment of the invention;

FIG. 6 is a cross-sectional view of a socket supporting a plurality of contact probes of the first structure example;

FIG. 7 is a cross-sectional view of second structure example of a contact probe according to another embodiment of the invention;

FIG. 8 is a cross-sectional view of third structure example of a contact probe according to other embodiment of the invention;

FIG. 9 is a cross-sectional view of forth structure example of a contact probe according to other embodiment of the invention;

FIG. 10 is a cross-sectional view of fifth structure example of a contact probe according to other embodiment of the invention;

FIG. 11 is a cross-sectional view of sixth structure example of a contact probe according to other embodiment of the invention;

FIG. 12 is a cross-sectional view of seventh structure example of a contact probe according to other embodiment of the invention;

FIG. 13 is an outline cross-sectional view of a structure example of a conventional contact probe;

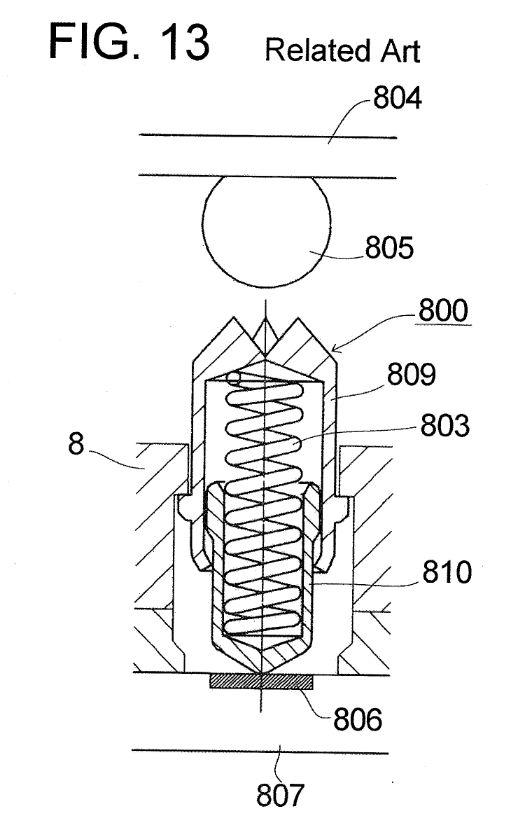

FIG. 14A to FIG. 14F are explanatory process flow views of a manufacturing method of a bag-like hollow plunger used for the conventional contact probe;

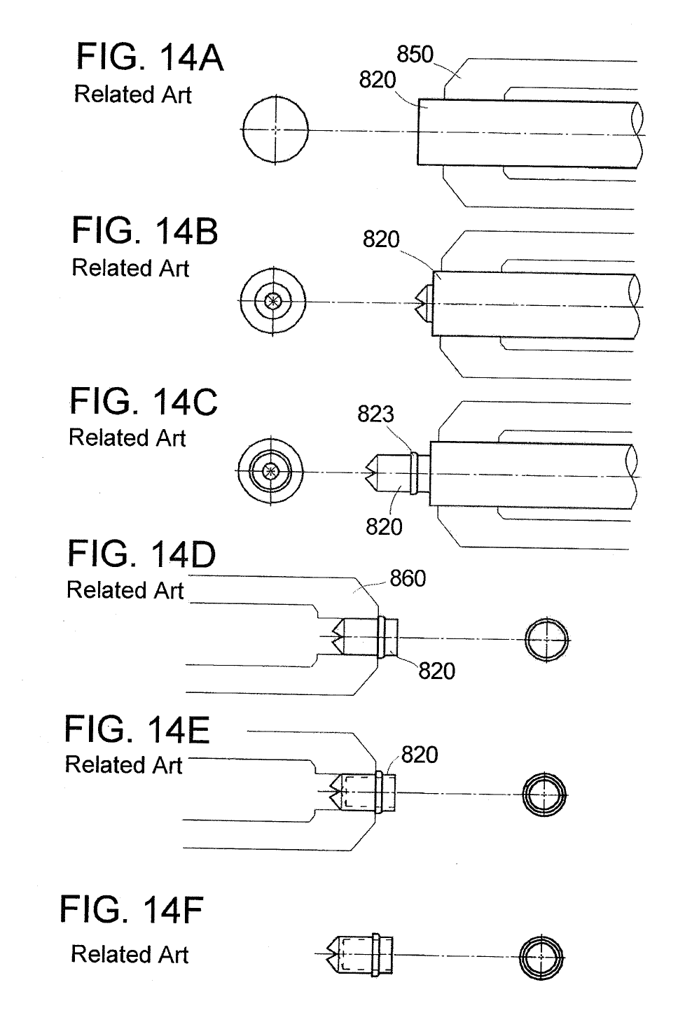

FIG. 15 is an outline cross-sectional view of another structure example of a conventional contact probe; and

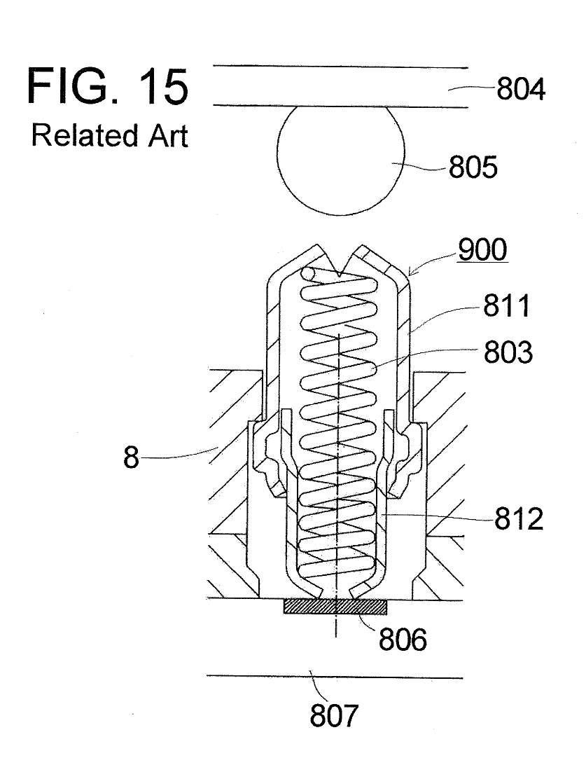

FIG. 16A, 16B are explanatory process flow views of a plunger made by a press working and a rounding process used for a conventional contact probe.

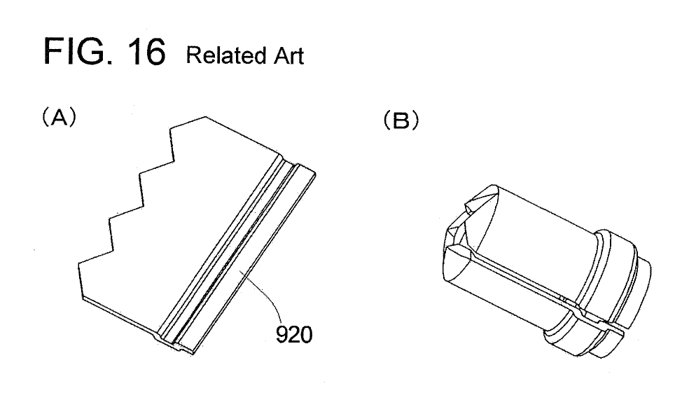

### DETAILED DESCRIPTION OF THE INVENTION

The invention will now be described based on the following embodiments which do not intend to limit the scope of the present invention but exemplify the invention. All of the features and the combinations thereof described in the embodiments are not necessarily essential to the invention.

(Manufacturing Method 1 of a Tube Plunger)

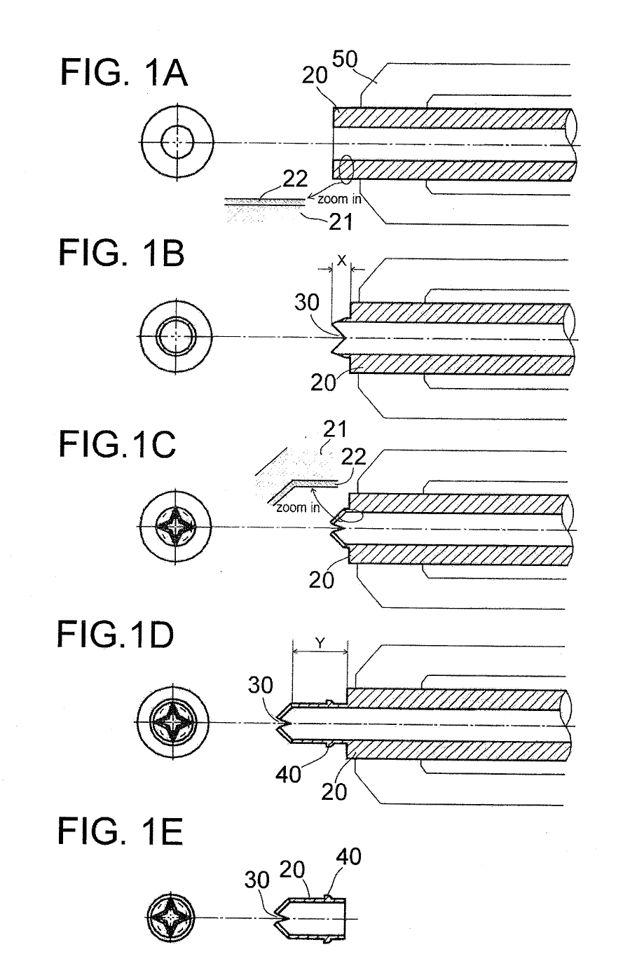

FIG. 1A to FIG. 1E are explanatory process flow views of manufacturing method 1 of a tube plunger according to an embodiment of the invention. First of all, a tubular metal 20 is held with a chuck 50 of a machine tool such as lathes as shown in FIG. 1A. As shown in enlarged parts of FIG. 1A and FIG. 1C, the tubular metal 20 is a gold clad tube, which includes a mother member 21 of electro conductive metal such as copper (Cu) or copper alloy etc. and a gold layer 22 formed on at least inner surface of the mother member 21 by thermo compression bonding etc. Instead of the gold layer 22, it is available a layer of a precious metal (for example platinum, palladium etc.) other than gold, and also available a precious-metal alloy (for example gold alloy, platinum alloy, palladium alloy etc.) of which principal ingredient is a precious metal. The process of manufacturing will be sequentially explained below.

### Process of Reducing Diameter and Process of Cutting Out

As shown in FIG. 1B, a tip part (that is a side surface including the tip) of the tubular metal 20 is shaved (cut away) to be a small outside diameter in a range of prescribed length X (process of reducing diameter). The tip part of the small outside diameter is cut to make prescribed number (here four) notches 30 which are grooves by cutting out (process of cutting out). The notches 30 of the tubular metal 20 are provided for contact with an object such as a solder ball at a plurality of contact points for example four points. For example, a shape of notch 30 is an isosceles triangle or an equilateral triangle.

### Process of Bending

As shown in FIG. 1C, a part of the small outside diameter, that is the tip part remained, of the tubular metal 20 is bent inside by pushing from outside for example. In this process, the part not made the small outside diameter does not bend because rigidity is large enough, and the part of the small outside diameter bends by press from the outside because the rigidity is small. Therefore, it is convenient that only a necessary part can be bent inside with the press from the outside by making only the part that should be bent inside the small outside diameter. The contact with the object such as the solder ball is improved by bending inside, and the bent part is available for a stopper for a coil spring to be inserted into the tubular metal 20 not to escape.

### Process of Convex Part Working

As shown in FIG. 1D, a part of the tubular metal 20 from the bending point of the process of bending to an end side is shaved to be a small outside diameter in a range of the prescribed length Y, so that convex part 40 of a large diameter is made partly. The convex part 40 is zonal that rounds outer of the tubular metal 20. A position where the convex part 40 is formed is a middle part inclined to the end side within the range of prescribed length Y. As described later, the convex part 40 of the larger diameter is provided for a stopper not to escape from a housing of a socket or one of a pair of plungers.

### Process of Cutting Off

As shown in FIG. 1E, the part of the small diameter of the tubular metal 20 is cut off at the end side edge in the range of prescribed length Y where was made to be the small diameter in the process of convex part working, and then a tube plunger is completed.

It is also available tubular metals 20 that do not provide with a gold layer 22 internally. In this case, a layer of precious metal or a layer of alloy of which principal ingredient is precious metal should be plated on at least the inner surface of the tubular metal 20 after the process of cutting off.

(Manufacturing Method 2 of a Tube Plunger)

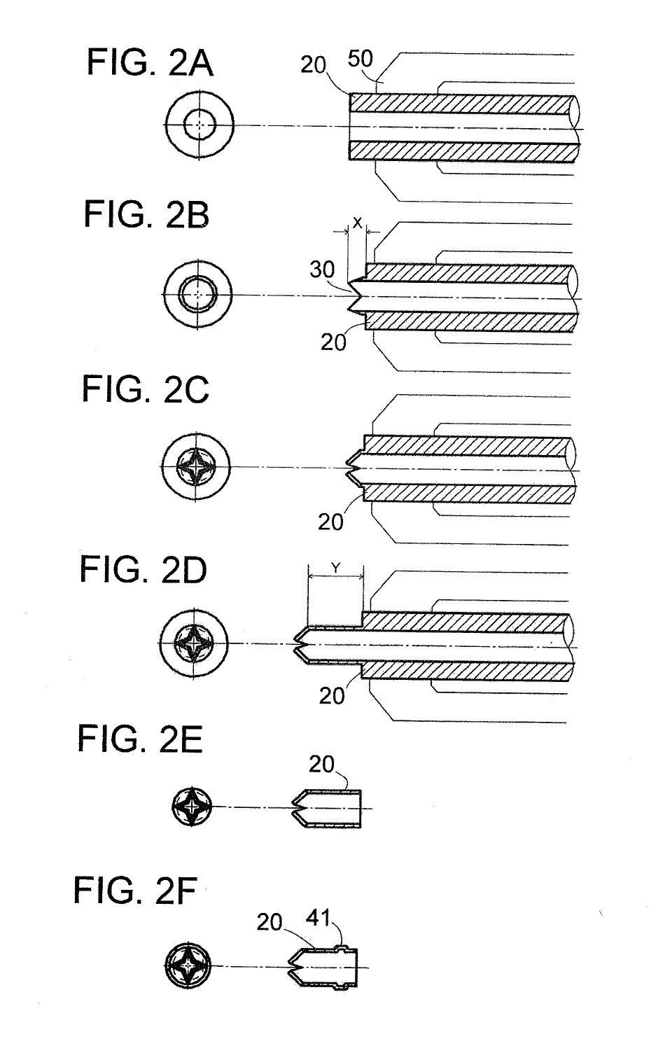

FIG. 2A to FIG. 2F are explanatory process flow views of manufacturing method 2 of the tube plunger according to the embodiment of the invention. The processes shown FIG. 2A to FIG. 2C, that is from the process of reducing diameter to the process of bending are similar to above-mentioned manufacturing method 1. Hereinafter, following processes will be explained.

### Process of Outside Diameter Working

As shown in FIG. 2D, a part of the tubular metal 20 from the bending point of the process of bending to an end side is shaved to be a small outside diameter in a range of the prescribed length Y. It differs from manufacturing method 1 that the convex part is formed in another process.

### Process of Cutting of

As shown in FIG. 2E, the part of the small diameter of the tubular metal 20 is cut off at the end side edge in the range of prescribed length Y where was made to be the small diameter in the process of outside diameter working.

### Process of Convex Part Working

As shown in FIG. 2F, a convex part 41 is formed outside of the small diameter part of the tubular metal 20 of which outside diameter was reduced in the process of outside diameter working. The convex part 41 can be formed by well-known sheet metal working technology (for example, technology described in Japanese Patent Application Laid-Open No. 2006-326662). And then, the tube plunger is completed. The convex part 41 is also provided for a stopper not to escape from the housing or one of a pair of plungers.

In the manufacturing method 2, it is also available tubular metals 20 that do not provide with the gold layer 22 internally. In this case, the layer of precious metal or a layer of alloy of which principal ingredient is precious metal should be plated on at least the inner surface of the tubular metal 20 after the process of cutting off and more preferable after the process of convex part working.

(Manufacturing Method 3 of a Tube Plunger)

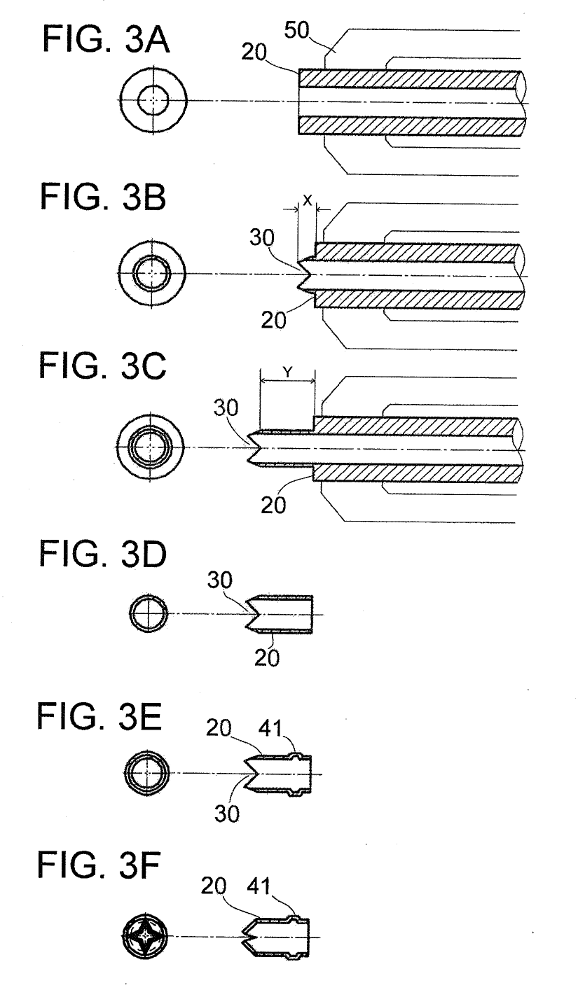

FIG. 3A to FIG. 3F are explanatory process flow views of manufacturing method 3 of the tube plunger according to the embodiment of the invention. The processes shown FIG. 3A and FIG. 3B, that is the process of reducing diameter and process of cutting notches are similar to above-mentioned manufacturing method 1. Hereinafter, following processes will be explained.

### Process of Outside Diameter Working

As shown in FIG. 3C, a part of the tubular metal 20 from the end side edge of the small diameter part in the range of the prescribed length X to an end side is shaved to be a small outside diameter in a range of the prescribed length Y. It differs from manufacturing method 1 that the convex part is formed in another process and that bending of the tip part is prosecuted in after process.

### Process of Cutting of

As shown in FIG. 3D, the part of the small diameter of the tubular metal 20 is cut off at the end side edge in the range of prescribed length Y where was made to be the small diameter in the process of outside diameter working.

### Process of Convex Part Working

As shown in FIG. 3E, a convex part 41 is formed outside of the small diameter part of the tubular metal 20 of which outside diameter was reduced in the process of the outside diameter working. The forming of the convex part 41 may be done by well-known sheet metal working for example.

### Process of Bending

As shown in FIG. 3F, a part remained by forming the notches 30 (in other words, a part or all of the range of the prescribed length X from the tip end) of the tubular metal 20 is bent inside, and then the tube plunger is completed. In case of the process of bending in the manufacturing method 3, the process of bending may be prosecuted by swage working etc. because a part except for the part to be bent is already reduced to be the small diameter different form the above-mentioned manufacturing method 1 and 2. Farther, the process of bending may be prosecuted before the process of convex part working.

In the manufacturing method 3, it is also available tubular metals 20 that do not provide with the gold layer 22 internally. In this case, the layer of precious metal or a layer of alloy of which principal ingredient is precious metal should be plated on at least the inner surface of the tubular metal 20 after the process of cutting off and more preferable after the process of convex part working and bending working.

(Manufacturing Method 4 of a Tube Plunger)

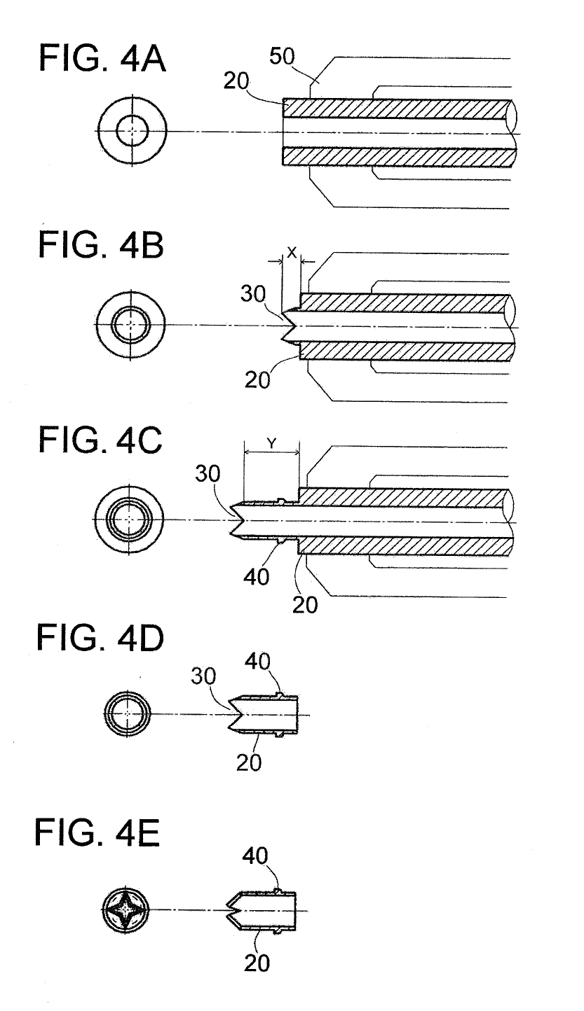

FIG. 4A to FIG. 4E are explanatory process flow views of manufacturing method 4 of the tube plunger according to the embodiment of the invention. The processes shown FIG. 4A and FIG. 4B, that is the process of reducing diameter and process of cutting notches are similar to above-mentioned manufacturing method 1. Hereinafter, following processes will be explained.

### Process of Convex Part Working

As shown in FIG. 4C, a part of the tubular metal 20 from the end side edge of the small diameter part in the range of the prescribed length X to an end side is shaved to be a small outside diameter in a range of the prescribed length Y, so that convex part 40 of a large diameter is made partly. The convex part 40 is zonal that rounds outer of the tubular metal 20.

### Process of Cutting of

As shown in FIG. 4D, the part of the small diameter of the tubular metal 20 is cut off at the end side edge in the range of prescribed length Y where was made to be the small diameter in the process of convex part working.

### Process of Bending

As shown in FIG. 4E, a part remained by forming the notches 30 (in other words, a part or all of the range of the prescribed length X from the tip end) of the tubular metal 20 is bent inside, and then the tube plunger is completed. The process of bending may be prosecuted by the swage working etc. as same as the above-mentioned manufacturing method 3.

In the manufacturing method 4, it is also available tubular metals 20 that do not provide with the gold layer 22 internally. In this case, the layer of precious metal or a layer of alloy of which principal ingredient is precious metal should be plated on at least the inner surface of the tubular metal 20 after the process of cutting off and more preferable after the process of the bending working.

According to the manufacturing method 1 to 4 of the tube plunger, which is made from the tubular metal 20 as a start member provided with the mother member 21 of electro conductive metal and the gold layer 22 formed on at least inner surface thereof, so that the quality control of plating is not necessary different from the bag-like hollow plunger as mentioned in the related art 1. If the tubular metal 20 as the start member not provided with the gold layer 22 to be formed on the inner surface, the tubular metal 20 is opened at both end, so that the quality control of plating is not difficult different from the bag-like hollow plunger as mentioned in the related art 1. Therefore, in comparison with the plunger of the related art 1, the plunger with the gold layer 22 of high quality inside thereof can be realized.

Further, the tube plunger according to the method 1 to 4 is made without the press working and the rounding process different from the plunger in the related art 2, so that the tube plunger need not the special metal mold for the press working, is suitable for the minute diameter contact probe, and is preferable because of enabling to avoid the slit in the longitudinal direction on the side surface of the plunger. Further, in the method 1 to 4, it is not necessary to make the hole by drilling different from the plunger in the related art 1 so that manufacturing steps are simplified.

(First Structure Example of a Contact Probe)

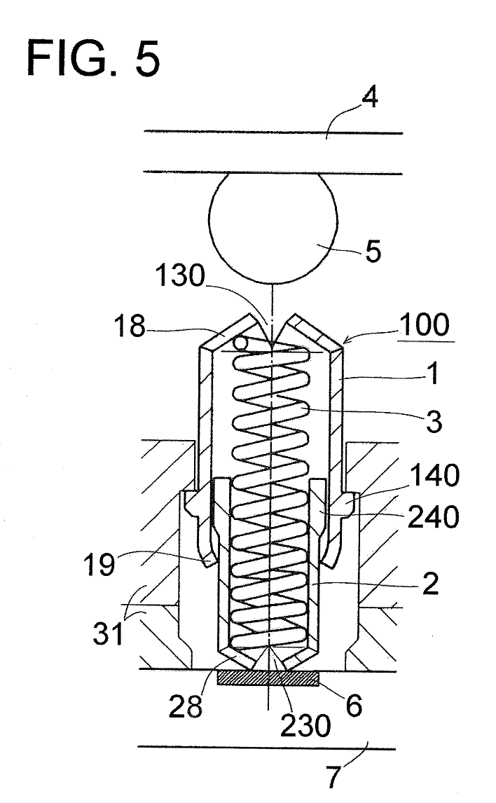

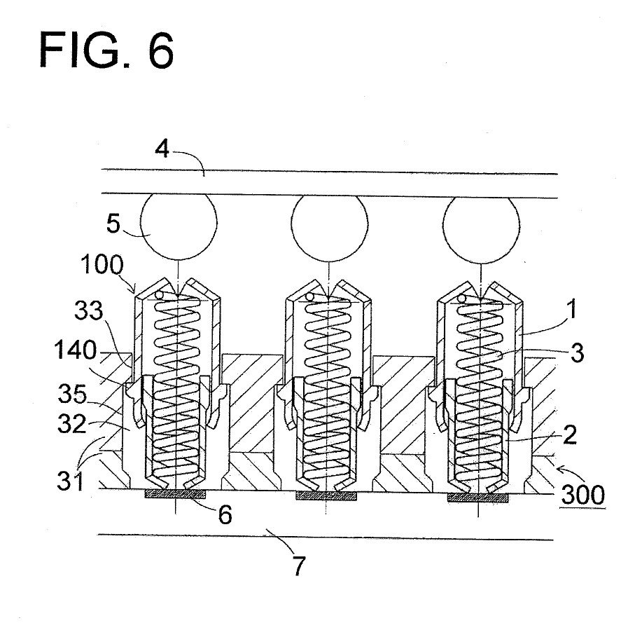

FIG. 5 is a cross-sectional view of first structure example of a contact probe according to the embodiment of the invention and FIG. 6 is a cross-sectional view of a socket 30 supporting a plurality of contact probes 100 as shown in FIG. 5.

As shown in the FIG. 5, the contact probe 100 is provided with first tube plunger 1, second tube plunger 2 and a coil spring 3. The contact probes 100 are supported by a housing 31 (insulation support body) as discussed below. The first tube plunger 1 is a connection component with a test object 4 (DUT), and the second tube plunger 2 is a connection component with a test board 7 (DUT board), that is, the contact probe 100 makes interconnection between the test object 4 and the test board 7.

The test object 4 is semiconductor integrated circuit for example of which electrodes are arranged in a fixed interval. In case of FIG. 6, solder balls 5 as electrode bumps are arranged in a fixed interval. The test board 7 has contact pads 6 in the fixed interval corresponding to the solder balls 5 and electrode pads (not shown) corresponding to solder balls 5. The electrode pads are connected to a measuring instrument side.

As shown in FIG. 5, the diameter of the first tube plunger 1 is larger than that of the second tube plunger 2. An end side of the second tube plunger 2 is inside of the first tube plunger 1, so that the second tube plunger 2 is slidable inside of the first tube plunger 1 relatively. At least a part of the end side of the second tube plunger 2 which is inside of the first tube plunger 1 is a zonal convex part 240. The end 19 of the first tube plunger 1 is swaged under the condition that the end side of the second tube plunger 2 is inside of the first tube plunger 1, so that escape (drop out) of the second tube plunger 2 is prevented.

The coil spring 3 is formed by a general material such as a piano wire or a stainless steel wire for example. The coil spring 3 is inside of the first and second tube plungers 1, 2 so that the coil spring 3 energizes plungers 1, 2 in a direction to separate plunger 1 from plunger 2. Therefore, it causes plungers 1, 2 to provide contact force on the solder ball 5 of the test object 4 and the contact pad 6 of the test board 7 respectively.

Four notches 130 of an isosceles triangle or an equilateral triangle for example are cut out from the tip part of the first tube plunger 1 in the same interval, so that four triangle sections 18 (that is, the tip part remained) with a sharp tip are formed. Each triangle section 18 is bent inside. In the same way, four notches 230 of an isosceles triangle or an equilateral triangle for example are cut out from the tip part of the second tube plunger 2, so that four triangle sections 28 with a sharp tip are formed. Each triangle section 28 is bent inside. Therefore, contact (sureness and durability of contact) between the first tube plunger 1 and the solder ball 5 of the test object 4 and between second tube plunger 2 and the contact pad 6 of the test board 7 are improved, and escape of the coil spring 3 is prevented.

A zonal convex part 140 (flange part) is formed on a side surface of the first tube plunger 1, and the zonal convex part 140 prevents to escape the contact probe 100 from housing 31. The first and second tube plunger 1, 2 have not slit in the side surface. They are manufactured for example by either of the above manufacturing methods 1 to 4. In FIGS. 5 and 6, the first and second tube plunger 1, 2 is shown for example of which the convex parts 140, 240 (zonal convex) are made by shaving according to the manufacturing methods 1 or 4.

An example of a manufacture process of the contact probe 100 will be explained hereinafter. First, for example the first and second tube plunger 1, 2 are made by either of the above manufacturing methods 1 to 4. But, the end 19 of the first tube plunger 1 is not swaged yet. Then, a part of one end side of the coil spring 3 is inserted into the inside of the second tube plunger 2. At this time, the tip part (the triangle sections 28 bent inside) of the second tube plunger 2 becomes a stopper for the coil spring 3 not to escape. Next, a part of the end side of the second tube plunger 2 and a part of the other end side of the coil spring 3 are inserted into the inside of the first tube plunger 1. At this time, the tip part (the triangle sections 18 bent inside) of the first tube plunger 1 becomes a stopper for the coil spring 3 not to escape. The end 19 of the first tube plunger 1 is swaged under the condition that the end side of the second tube plunger 2 is inside of the first tube plunger 1, so that escaping of the second tube plunger 2 is prevented.

According to the first structure example of the contact probe described above, following effects can be obtained. That is, the first and second tube plungers 1, 2 manufactured for example by either of the manufacturing methods 1 to 4 have not a slit in the side surface, therefore, the plungers 1, 2 can slide more smoothly and avoid degrading of electrical characteristics caused by the slit in comparison with the contact probe in the related art 2 which has the slit in the side surface. The plungers 1, 2 can realize a minute diameter contact probe corresponding to the test object with terminal arrays of narrow pitch because working accuracy is good and making the plunger to a minute diameter is easy. Further, the plungers 1, 2 can realize a high quality contact probe because the plungers 1, 2 are respectively provided with the gold layer of high quality inside thereof in comparison with the plunger in the related art 1 as mention above.

(A Structure Example of a Socket Based on the First Structure Example)

As shown in FIG. 6, a socket 300 provided with a housing 31 (insulation support body) which is formed hollow 32 (hole) in a prescribed interval to arrange parallel contact probes 100 each other, and the contact probes 100 which are inserted into the hollow 32 respectively. Specifically, the first and second tube plunger 1, 2 and the coil spring 3 are assembled integrally into the contact probe 100 as shown in FIG. 5, and then the contact probes 100 are inserted and put into the hollow 32 of the housing 31 respectively. The side surface of the first tube plunger 1 is supported by (engage with) an open side slidable part 33 of a top end of the hollow 32. A middle part 35 except for the open side slidable part 33 of the hollow 32 has a larger inner diameter than that of the part 33, so that the convex part 140 can move freely in middle part 35. The convex part 140 is stopped by the open side slidable part 33 so that escaping of the first tube plunger 1 is prevented. The housing 31 is a structure of several layers (two layers in the figure) so as to set the contact probe 100 in the hollow 32 or secure enough depth of the hollow 32.

When measuring is to be done by using the socket 300 assembled as mentioned in FIG. 6, the socket 300 is set and positioned on the test board 7. As a result, the tip of the second tube plunger 2 is elastically urged to be contact with the contact pad 6 of the test board 7 because of shrinkage of a length of the coil spring 3. Under the condition in which the test object 4 such as semiconductor integrated circuit is not set on the socket 300, the first tube plunger 1 slides to project until the convex part 140 is stopped by the open side slidable part 33, so that a projection length is maximum. When the test object 4 is set on the socket 300 and faces to the housing 31 of the socket 300 in a prescribed interval, the first tube plunger 1 withdraws and the coil spring 3 is further compressed, so that the tip of the first tube plunger 1 is elastically urged to be contact with the solder ball 5 of the test object 4. The measuring of the test object 4 is carried out under this condition.

(Second Structure Example of a Contact Probe)

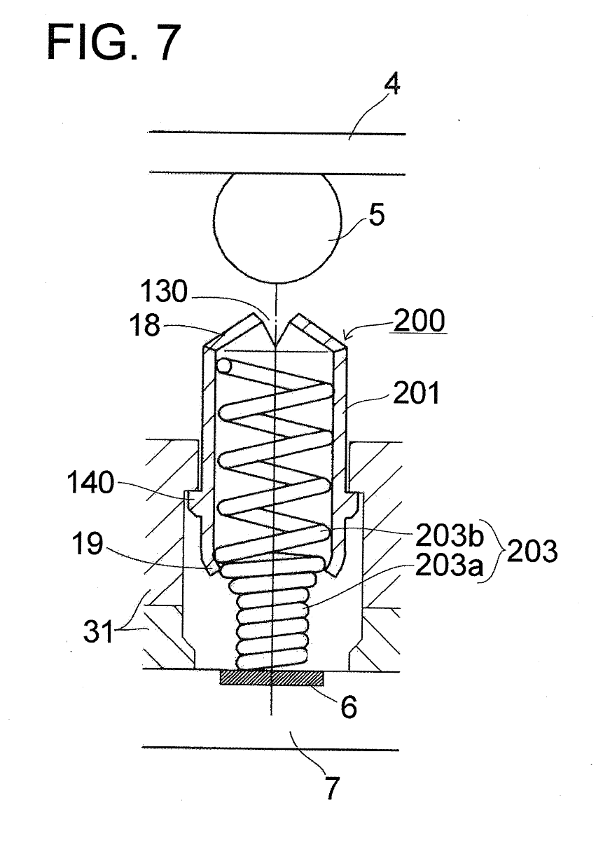

FIG. 7 is a cross-sectional view of second structure example of a contact probe according to the embodiment of the invention. In the contact probe 200 of the second structure example, it is mainly deferent in comparison with the contact probe 100 of the first structure example that the second tube plunger 2 is omitted from the contact probe 200 and a tip of a coil spring 203 is made to be a connection part to the test board 7. And other structure is as same as the contact probe 100. Hereinafter, the difference will be explained mainly.

The coil spring 203 has a tightly-wound part 203a and a coarsely-wound part 203b which is compressible. A diameter of the coarsely-wound part 203b is larger than that of the tightly-wound part 203a, and the coarsely-wound part 203b is contained inside of a tube plunger 201 (as same as the structure of the first tube plunger 1 of the first structure example). The tightly-wound part is a part including a plurality of winds which contact (cohere) each other in an axial direction of the spring 203 under the condition of non-use of the contact probe 200, that is, under the condition of which the tip of the tube plunger 201 does not contact with the solder ball 5 of the test object 4. Under the condition that the coarsely-wound part 203b is contained inside of the plunger 201, the end 19 of the plunger 201 is swaged so as to be a smaller inner diameter than an outer diameter of the coarsely-wound part 203b with preventing the coil spring 203 to escape. Under the condition of using of the contact probe 200 (during measuring of the test object 4), the coil spring 203 energizes the plunger 201 in the direction to separate plunger 201 from the coil spring 203, so that it causes plunger 201 to provide a contact force on the solder ball 5 of the test object 4 and also causes the coil spring 203 itself to provide a contact force on the pad 6 of the test board 7.

Preferably the tightly-wound part 203a is a inclined coil part (in the figure, winds thereof are inclined top right to bottom left) so as to be nonparallel with respect to a plane perpendicular to a winding axis direction. Therefore, a tip of the coil spring 203 contacts with the contact pad 6 of the test board 7 at a point or like a short line, so that a contact region with the contact pad 6 always becomes constant. Therefore, the contact between the tip of the coil spring 203 and the contact pad 6 of the test board 7 becomes more secure in comparison with the winds are not inclined.

The second structure example is also able to obtain the similar effect as the first structure example. That is, the tube plunger 201 has not a slit in the side surface, therefore, the plunger 201 can slide smoothly and avoid degrading of electrical characteristics caused by the slit. The plunger 201 can realize a minute diameter contact probe because working accuracy is good and making the plunger to a minute diameter is easy. Further, the plunger 201 can realize a high quality contact probe because the plunger 201 is provided with the gold layer of high quality inside thereof. A socket can be composed of supporting a plurality of the contact probes 200 in the same way as shown in FIG. 6, so that the measuring of the test object can be carried out similarly.

(Third Structure Example of a Contact Probe)

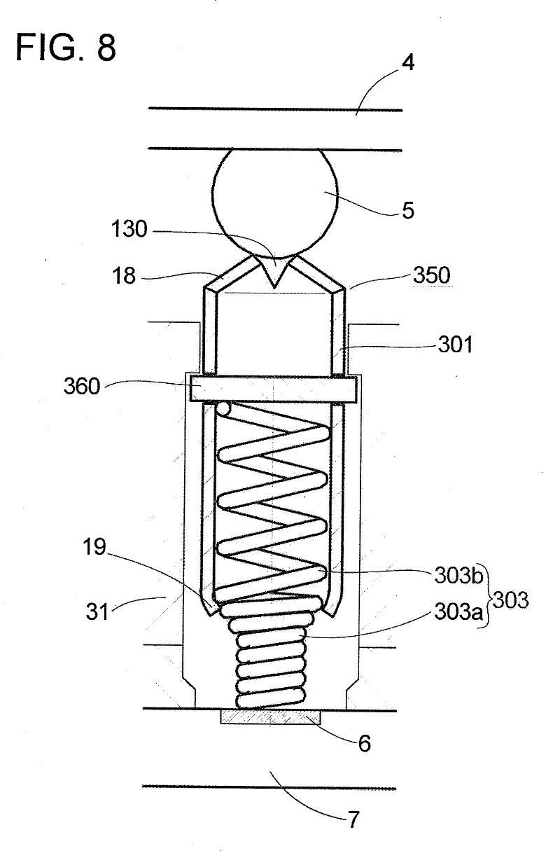

FIG. 8 is a cross-sectional view of third structure example of a contact probe according to other embodiment of the invention. In the third structure example, the contact probe 350 is provided with a retaining member 360 like a pin which goes through a tube plunger 301 in a diameter direction different from the contact probe 200 of the second structure example, and an end of a coil spring 303 (with a tightly-wound part 303a and a coarsely-wound part 303b) is received and retained by the retaining member 360. Both parts of the retaining member 360 project from outer surface of the tube plunger 301 make to be stoppers not to escape from the housing 31 instead of the convex part 140 of the second structure example. Therefore, the tube plunger 301 does not have the convex part 140. Other components are similar to the contact probe 200 in the second structure example. The third structure example is also able to obtain the similar effect as the second structure example.

(Fourth Structure Example of a Contact Probe)

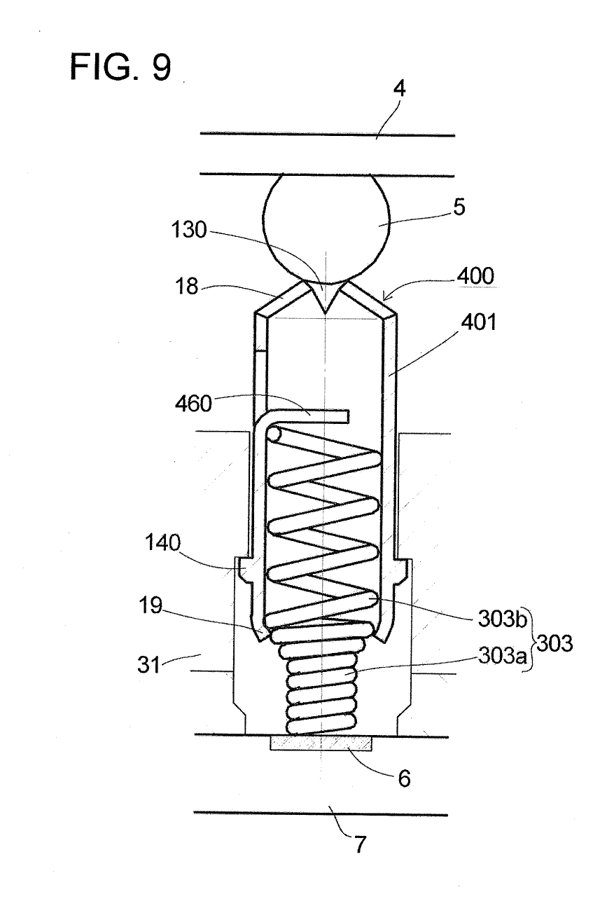

FIG. 9 is a cross-sectional view of forth structure example of the contact probe according to other embodiment of the invention. In the fourth structure example, the contact probe 400 is provided with a tube plunger 401 of which side part is cut and bent inside to make a tab 460 as a retaining member different from the contact probe 200 of the second structure example, and an end of a coil spring 303 is received and retained by the tab 460. The tab 460 is positioned at a tip side of the tube plunger 401 in comparison with a position of the convex part 140. Other components are similar to the contact probe 200 in the second structure example. The fourth structure example is also able to obtain the similar effect as the second structure example.

(Fifth Structure Example of a Contact Probe)

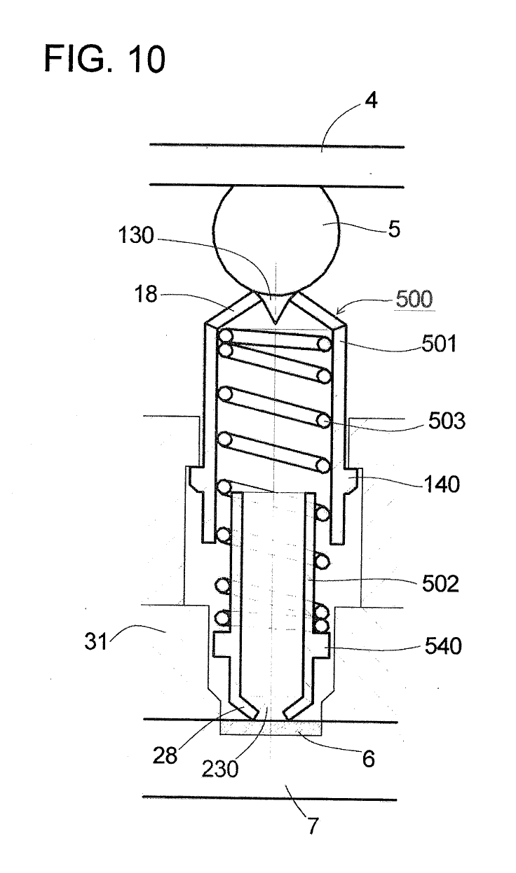

FIG. 10 is a cross-sectional view of fifth structure example of a contact probe according to other embodiment of the invention. In the fifth structure example, the contact probe 500 is different from the contact probe 100 of the first structure example, that is, a coil spring 503 is outside of second tube plunger 502 and inside of first tube plunger 501. The end of the first tube plunger 501 is not swaged. The second tube plunger 502 is corresponding to a plunger which made a diameter smaller than that of the first tube plunger 501. A gold layer inside of the second tube plunger 502 is unnecessary because the inside of the second tube plunger 502 is not a slide surface (not a contact surface). A convex part 540 of the second tube plunger 502 receives and retains an end of the coil spring 503, and makes to be a stopper not to escape from the housing 31. Other components are similar to the contact probe 100 in the first structure example. The fifth structure example is also able to obtain the similar effect as the first structure example.

(Sixth Structure Example of a Contact Probe)

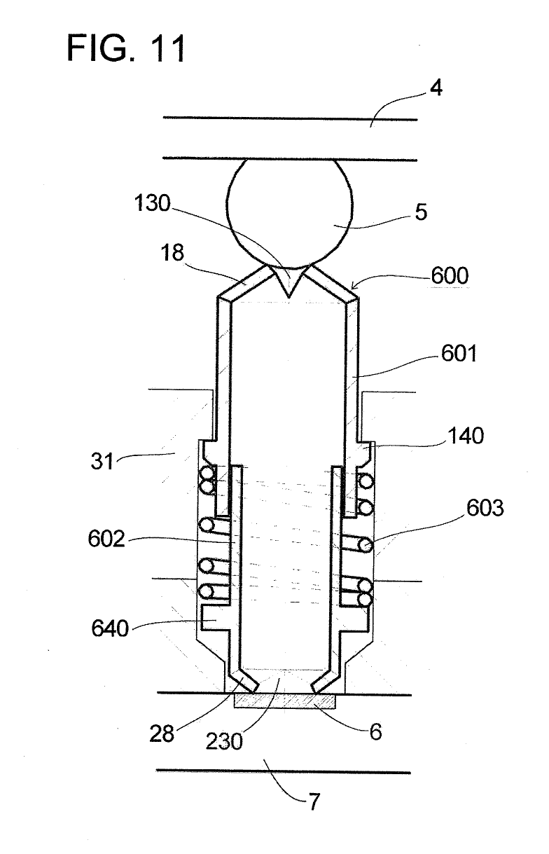

FIG. 11 is a cross-sectional view of sixth structure example of a contact probe according to other embodiment of the invention. The contact probe 600 of the sixth structure example is different from the contact probe 500 of the fifth structure example, that is, a coil spring 603 is outside of first and second tube plunger 601, 602. One end and the other end of the coil spring 603 are received and retained by convex parts 140, 640 (held between convex parts 140, 640). Other components are similar to the contact probe 500 in the fifth structure example. The sixth structure example is also able to obtain the similar effect as the fifth structure example.

(Seventh Structure Example of a Contact Probe)

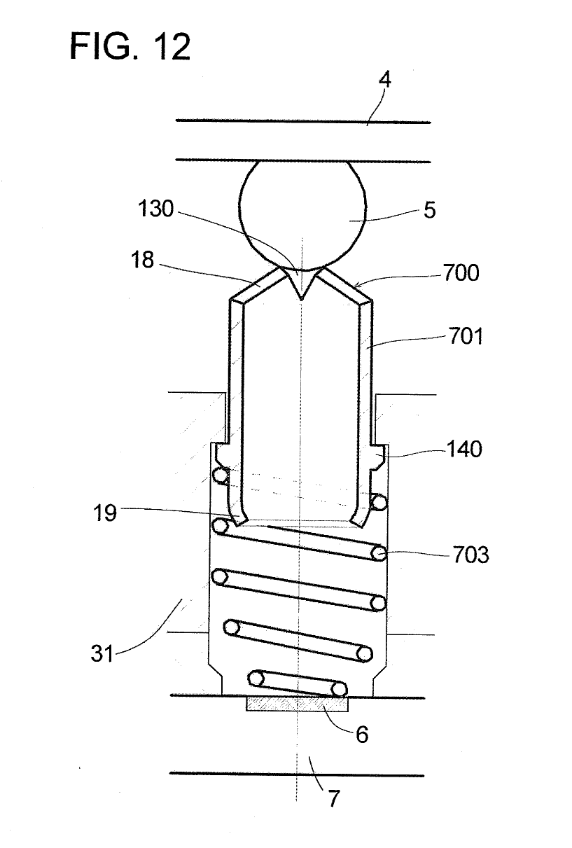

FIG. 12 is a cross-sectional view of seventh structure example of a contact probe according to other embodiment of the invention. The contact probe 700 of the seventh structure example is different from the contact probe 200 of the second structure example, that is, a bottom end side of a coil spring 703 is outside of a tube plunger 701 (similar to the tube plunger 201 of the second structure example). The bottom end of the coil spring 703 is received and retained by the convex part 140 of the tube plunger 701. A gold layer inside of the tube plunger 701 is unnecessary because the inside of the tube plunger 701 is not a slide surface (not a contact surface).

Described above are explanations based on the embodiments. The description of the embodiments is illustrative in nature and various variations in constituting elements and processes involved are possible. Those skilled in the art would readily appreciate that such variations are also within the scope of the present invention. Examples of the variations are explained hereafter.

While it is explained the case in the embodiments that the notches are cut out from the tip part of the tube plunger, the notches may omit if such processing is unnecessary according to a use. In this case, the process of reducing diameter and the process of outside diameter working are able to prosecute in one process in the manufacturing method 3 of the tube plunger as shown in FIG. 3A to FIG. 3F. They can prosecute the same way in the method 4 as shown in FIG. 4A to FIG. 4E.

While it is explained the case in the embodiments that the process of reducing diameter of the tubular metal is prosecuted in the manufacturing method of the tube plunger, the process of reducing diameter is unnecessary when the tubular metal prepared is thin enough and small enough in the diameter. In this case, the convex part 40 is formed by the sheet metal processing such as the manufacturing method 2 or 3.

While it is explained the case in the embodiments that the tip part (a side part including the tip) of the tube plunger is bent inside, on the other hand, a part of the side except for the tip part of the tube plunger may be bent to make stopper for the coil spring not to escape without bending of the tip part in the example of the variation. Technologies of public knowledge (for example, Japanese Patent Application Laid-Open No. 2004-61180) can be used for such processing. Note that “be bent” includes a meaning of process “to project inside (form a convex inside)”.

1. A contact probe for electrical interconnection comprising:
at least one tube plunger free of slits; and
a coil spring, which is retained by the tube plunger, the coil spring having an end which touches to the tube plunger, so that the coil spring urges the plunger and a a retained part of the coil spring in opposite directions.

2. The contact probe according to claim 1, wherein
a part of the coil spring is inside of the tube plunger, and
a tip part of the tube plunger is a connection part, is bent inside, and is a stopper retaining the coil spring.

3. The contact probe according to claim 1, wherein
a part of the coil spring is inside of the tube plunger,
a tip part of the tube plunger is a connection part, and
a side part of the tube plunger is bent inside and is a stopper for retaining the coil spring.

4. The contact probe according to claim 1, wherein
a part of the coil spring is inside of the tube plunger,
a tip part of the tube plunger is a connection part, and
the coil spring is retained by a stopper member penetrating through the tube plunger along a diameter of the tube plunger.

5. The contact probe according to claim 1, wherein
a part of the coil spring is outside of the tube plunger,
a tip part of the tube plunger is a connection part, and
a stopper part outside of the tube plunger retains the coil spring.

6. The contact probe according to claim 1, wherein at least a part, including a tip of the coil spring, is a tightly-wound part.

7. A contact probe for electrical interconnection comprising:
first and second tube plungers which are free of slits; and
a coil spring having a first end retained by a stopper part of the first tube plunger, and a second end retained by a stopper part of the second tube plunger, so that the coil spring urges the first and second tube plungers apart from each other.

8. The contact probe according to claim 7, wherein
the coil spring is inside of the first and second tube plungers,
each tip part of the first and second tube plungers is a connection part,
a side part of each of the first and second tube plungers is bent inside and is a stopper for retaining the coil spring, and
a bottom end side of the second tube plunger is located inside of the first tube plunger so the first and second tube plungers are slidable with respect to each other and the second tube plunger does not escape from the first tube plunger.

9. A socket comprising an insulating support body, and a plurality of the contact probes according to claim 1 supported by the insulating support body.

10. A socket comprising, an insulating support body, and a plurality of the contact probes according to claim 7 supported by the insulating support body.

11. A method of manufacturing a tube plunger comprising:
preparing a tubular metal provided with a layer of a precious metal or a precious-metal alloy of which a principal ingredient is a precious metal, and
bending, to inside the tubular metal, a side part of the tubular metal.

12. A method of manufacturing a tube plunger comprising:
bending, to inside, a side part of the tubular metal, and
after the bending, plating at least an inside of the tubular metal with a layer of a precious metal or a precious-metal alloy of which a principal ingredient is a precious metal.

13. The method of manufacturing a tube plunger according to claim 11, further comprising working a convex part outside of the tubular metal.

14. The method of manufacturing a tube plunger according to claim 12, further comprising working a convex part outside of the tubular metal.

15. The method of manufacturing a tube plunger according to claim 11, further comprising shaving a prescribed length of a tip part of the tubular metal to produce a reduced diameter part of the tubular member before bending, and bending, to the inside, the reduced diameter part.

16. The method of manufacturing a tube plunger according to claim 12, further comprising shaving a prescribed length of a tip part of the tubular metal to produce a reduced diameter part of the tubular member before bending, and bending, to the inside, the reduced diameter part.

17. The method of manufacturing a tube plunger according to claim 11, further comprising cutting a plurality of notches from a tip part of the tubular metal, and bending inside the tubular metal the tip part that remains.

18. The method of manufacturing a tube plunger according to claim 12, further comprising cutting a plurality of notches from a tip part of the tubular metal, and bending inside the tubular metal the tip part that remains.

19. A method of manufacturing a contact probe comprising:
preparing a first tubular metal provided with a layer of a precious metal or a precious-metal alloy of which a principal ingredient is a precious metal,
bending inside the first tubular metal a side part of the first tubular metal to form a first bent part, and
inserting one side of a coil spring inside of the first tubular metal, the first bent part being a first stopper for the coil spring, preventing escape of the coil spring from a first side of the first tubular metal.

20. The method of manufacturing a contact probe according to claim 19, further comprising, after inserting of the coil spring, forming a second stopper at a bottom side of the tubular metal, preventing the coil spring from escaping from a second side of the first tubular metal.

21. The method of manufacturing a contact probe according to claim 19, further comprising:
preparing a second tubular metal provided with a layer of a precious metal or a precious-metal alloy of which a principal ingredient is a precious metal,
bending inside the second tubular metal a side part of the second tubular metal to form a a second bent part, and
assembling the first and second tubular metals and the coil spring, so that bottom side of one of the first and second tubular metals is inside of the other of the first and second tubular metals, and the coil spring is inside of the first and second tubular metals and is retained between the first and second bent parts so that the coil spring cannot escape.
